(19) United States
(12) Patent Application Publication
(10) Pub. No.: US 2024/0266477 A1
(43) Pub. Date: Aug. 8, 2024

(54) LED LIGHT EMITTING DEVICE

(71) Applicants: Citizen Electronics Co., Ltd., Fujiyoshida-shi, Yamanashi (JP); Citizen Watch Co., Ltd., Nishitokyo-shi, Tokyo (JP)

(72) Inventors: You OTAKI, Fujiyoshida-shi, Yamanashi (JP); Takashi IINO, Fujiyoshida-shi, Yamanashi (JP); Sadato IMAI, Fujiyoshida-shi, Yamanashi (JP); Kazuki MATSUMURA, Fujiyoshida-shi, Yamanashi (JP)

(21) Appl. No.: 18/684,112

(22) PCT Filed: Aug. 30, 2022
(86) PCT No.: PCT/JP2022/032677

§ 371 Date: Feb. 15, 2024

(30) Foreign Application Priority Data
Aug. 31, 2021 (JP) 2021-141638

(51) Int. Cl. H01L 33/46; H01L 33/60

(52) U.S. Cl. CPC H01L 33/46; H01L 33/60

(57) ABSTRACT

An LED light emitting device capable of improving reliability is provided. An LED light emitting device has a mount substrate having a base, a reflection layer containing silver and laminated on the base, and a multilayer reflection film laminated on the reflection layer, an LED die emitting blue light and mounted in a light emitting area on the mount substrate, a sealing resin including fluorescent substance particles and sealing the LED die and the surface of the mount substrate within the light emitting area, and a DBR layer arranged on the undersurface of the LED die and shielding at least part of blue light emitted from the LED die, wherein the DBR layer is a layer in which a plurality of sets of dielectrics including a high-refractive index layer and a low-reflective index layer is laminated and the fluorescent substance particles precipitate within the sealing resin and form a fluorescent substance layer covering part of the lateral surface of the LED die and part of the surface of the multilayer reflection film within the light emitting area.

### FIELD

The present invention relates to an LED light emitting device.

### BACKGROUND

Various techniques are known which improve reliability in an LED light emitting device using a light emitting diode (LED) die as a light emitting element.

The LED light emitting device described in International Publication WO 2021/060531 may improve reliability, and maintain desired reflectance by flattening the surface of a high reflection coating arranged on the surface of an aluminum mount substrate to reduce pin holes in the high reflection coating.

A light emitting device is described in U.S. Pat. No. 9,865,783 in which an LED element having a low-refractive index layer on the bottom surface is arranged on a substrate which has a high-refractive index layer 400 nm thick and a low-refractive index layer 800 nm thick on the high-refractive index layer.

### SUMMARY

However, as the use of the LED light emitting device using an LED die as a light emitting element extends, it is desired to further improve the reliability of the LED light emitting device.

An object of the present disclosure is to provide an LED light emitting device capable of improving reliability.

The LED light emitting device according to the present disclosure has a mount substrate having a base, a reflection layer containing silver and laminated on the base, and a multilayer reflection film laminated on the reflection layer; an LED die emitting blue light and mounted in a light emitting area on the mount substrate; a sealing resin including fluorescent substance particles and sealing the LED die and the surface of the mount substrate within the light emitting area; and a DBR layer arranged on the undersurface of the LED die and shielding at least part of blue light emitted from the LED die, and the multilayer reflection film includes one TiO₂ layer and one SiO₂ layer, the DBR layer is a layer in which a plurality of sets of dielectrics including a high-refractive index layer and a low-refractive index layer is laminated, and the fluorescent substance particles precipitate within the sealing resin and form a fluorescent substance layer covering part of the lateral surface of the LED die and part of the surface of the multilayer reflection film within the light emitting area.

Further, in the LED light emitting device according to the present disclosure, it is preferable for the fluorescent substance layer to include a cohesive layer in which fluorescent substance particles cohere.

Further, in the LED light emitting device according to the present disclosure, it is preferable for the fluorescent substance layer to include a cohesive layer in which fluorescent substance particles cohere and a floating layer in which fluorescent substance particles float.

Further, it is preferable for the LED light emitting device according to the present disclosure to further has a circuit substrate fixed on the mount substrate and a wiring pattern arranged on the circuit substrate, for the LED die to have a transparent substrate, a semiconductor laminate having a light emitting layer laminated on the transparent substrate, and a pair of electrodes connected to the semiconductor laminate and emit blue light from the light emitting layer in response to a predetermined voltage being applied between the pair of electrodes via the wiring pattern, and for at least part of the fluorescent substance layer to be formed between the light emitting layer and the multilayer reflection film.

Further, in the LED light emitting device according to the present disclosure, it is preferable for the fluorescent substance particles to include first fluorescent substance particles and second fluorescent substance particles whose average particle diameter is smaller than that of the first fluorescent substance particles and for part of the second fluorescence substance particles to be arranged between the first fluorescence substance particles.

Further, in the LED light emitting device according to the present disclosure, it is preferable for the high-refractive index layer to be selected from a group including TiO₂, ZrO₂, ZnSe, Si₃N₄, Nb₂O₅, TaO₅, and HfO₂ and for the low-refractive index layer to be selected from a group including SiO₂, MgF₂, Al₂O₃, and CaF.

Further, it is preferable for the LED light emitting device according to the present disclosure to further has a metal film arranged between the undersurface of the LED die and the multilayer reflection film.

Further, it is preferable for the LED light emitting device according to the present disclosure to further has a transparent material arranged between the multilayer reflection film and the sealing resin.

Further, it is preferable for the LED light emitting device according to the present disclosure to further has a die bond material for mounting the LED die on the mount substrate and for the die bond material to contain reflective material particles.

Further, in the LED light emitting device according to the present disclosure, it is preferable for the sealing resin to contain fillers of 5 to 10 wt % with respect to the sealing resin.

Further, in the LED light emitting device according to the present disclosure, it is preferable for the multilayer reflection film to include one TiO₂ layer and one SiO₂ layer.

Further, in the LED light emitting device according to the present disclosure, it is preferable for the film thickness of each of the TiO₂ layer and the SiO₂ layer configuring the multilayer reflection film to be 30 to 100 nm.

Further, the LED light emitting device according to the present disclosure has: a mount substrate having a base, a reflection layer containing silver and laminated on the base, and a high reflection coating formed of a plurality of oxide films whose refractive indexes are different and laminated on the reflection layer; a circuit substrate fixed on the mount substrate; a wiring pattern arranged on the circuit substrate; an LED die having a transparent substrate, a semiconductor laminate having an n-type semiconductor layer and a p-type semiconductor layer laminated on the transparent substrate, and a pair of electrodes connected to the wiring pattern and the semiconductor laminate and emitting blue light in response to a predetermined voltage being applied between the pair of electrodes; a sealing resin including fluorescent substances and scaling the LED die; and a light shielding layer arranged between the high reflection coating and the semiconductor laminate and shielding at least part of blue light.

Further, in the LED light emitting device according to the present disclosure, it is preferable for the light shielding layer to be a reflection film or a metal reflection film laminated on the opposite surface of the surface of the transparent substrate on which the semiconductor laminate is laminated, or both a reflection film and a metal reflection film.

Further, in the LED light emitting device according to the present disclosure, it is preferable for the LED die to adhere to the mount substrate with an adhesive member including a synthetic resin and for the high reflection coating to have a SiO₂ layer laminated above the reflection layer.

Further, in the LED light emitting device according to the present disclosure, it is preferable for the fluorescent substances to precipitate and be arranged so as to cover the surface of the mount substrate and at least part of the surface and the lateral surface of the LED die.

It is possible for the LED light emitting device according to the present disclosure to improve reliability.

### BRIEF DESCRIPTION OF DRAWINGS

FIG. 1A is a conceptual diagram showing a first state for explaining movement of silver, FIG. 1B is a conceptual diagram showing a second state, and FIG. 1C is a conceptual diagram showing a third state;

FIG. 2A shows a cross-sectional image of a multilayer reflection film when reflectance is comparatively high, FIG. 2B shows a cross-sectional image of the multilayer reflection film when reflectance is reduced, FIG. 2C shows a cross-sectional image of the multilayer reflection film when reflectance is further reduced, FIG. 2D shows a top surface image of the multilayer reflection film shown in FIG. 2A, and FIG. 2E shows a top surface image of the multilayer reflection film shown in FIG. 2C;

FIG. 3 shows a top surface image of the multilayer reflection film;

FIG. 4A is a plan diagram of an LED light emitting device according to an embodiment and FIG. 4B is a cross-sectional diagram along an A-A line shown in FIG. 4A;

FIG. 5 is a cross-sectional diagram of an LED die shown in FIG. 4A;

FIG. 6 is an enlarged diagram of a portion indicated by an arrow B in FIG. 4B;

FIG. 7A shows a state of a fluorescent substance layer in an LED light emitting device 1 and FIG. 7B shows a state of a fluorescent substance layer in an LED light emitting device 101;

FIG. 8A shows a cross-sectional image of the LED light emitting device 1 and FIG. 8B shows a cross-sectional image of an LED light emitting device 102, which is a modification example of the LED light emitting device 1;

FIG. 9A is a schematic diagram showing a mount substrate and an LED die used in the LED light emitting device 1, FIG. 9B is a schematic diagram showing a mount substrate and an LED die used in an LED light emitting device 105 according to a third comparative example, FIG. 9C is a schematic diagram showing a mount substrate and an LED die used in an LED light emitting device 104 according to a second comparative example, and FIG. 9D is a schematic diagram showing a mount substrate and an LED die used in an LED light emitting device 103 according to a first comparative example;

FIG. 10 is a diagram showing a mount substrate 110 of the LED light emitting devices 103 and 104 according to the comparative examples; and

FIG. 11 is a diagram showing a luminous flux residual ratio of each of the LED light emitting device according to the embodiment, the LED light emitting device according to the first comparative example, the LED light emitting device according to the second comparative example, and the LED light emitting device according to the third comparative example.

### DESCRIPTION OF EMBODIMENTS

Embodiments of the LED light emitting device according to the present invention are explained in detail with reference to the drawings. However, it should be noted that the technical scope of the present invention is not limited to those embodiments but encompasses the invention described in the claims and the equivalent thereof.

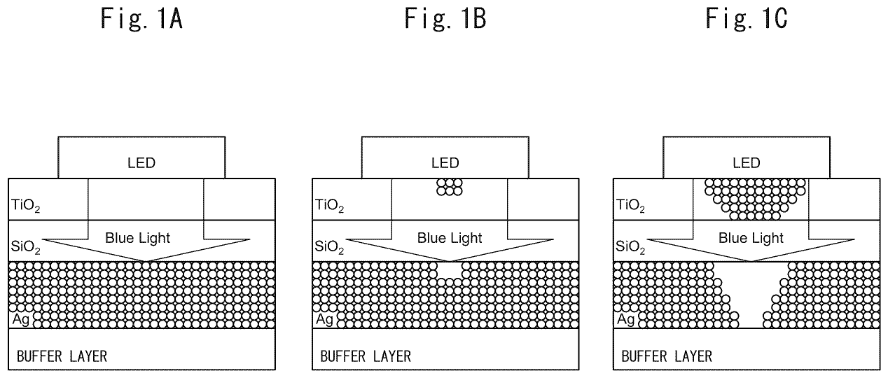

FIGS. 1A to 1C are conceptual diagrams explaining movement of silver found by the inventors of the present invention and FIG. 1A shows the first state, FIG. 1B shows the second state and FIG. 1C shows the third state. In each state, in the LED light emitting element, an LED die is arranged on the top surface of a multilayer reflection film. The multilayer reflection film includes a buffer layer, a reflection layer laminated on the buffer layer and containing silver, a silica (SiO₂) layer laminated on the reflection layer, and a titanium dioxide (TiO₂) layer laminated on the silica layer.

In the first state, although the reflection layer is irradiated with blue light by the LED die via the titanium dioxide layer and the silica layer, silver contained in the reflection layer has not moved. When time elapses from the first state, the silver starts to move to the titanium dioxide layer (see second state). When time elapses further from the second state, the movement of the silver continues and a void, which is part in the reflection layer from which the silver has disappeared, is formed and the buffer layer is exposed, which is the lower layer of the reflection layer (see third state).

As shown in the third state, when the void is formed in the reflection layer and the buffer layer is exposed, the reflectance of the reflection layer is reduced and the amount of light emitted from the LED light emitting element decreases. Further, since the silver moves to the titanium dioxide layer, the high reflection function of the high reflection coating formed by the silica layer and the titanium dioxide layer is reduced and the amount of light emitted from the LED light emitting element further decreases.

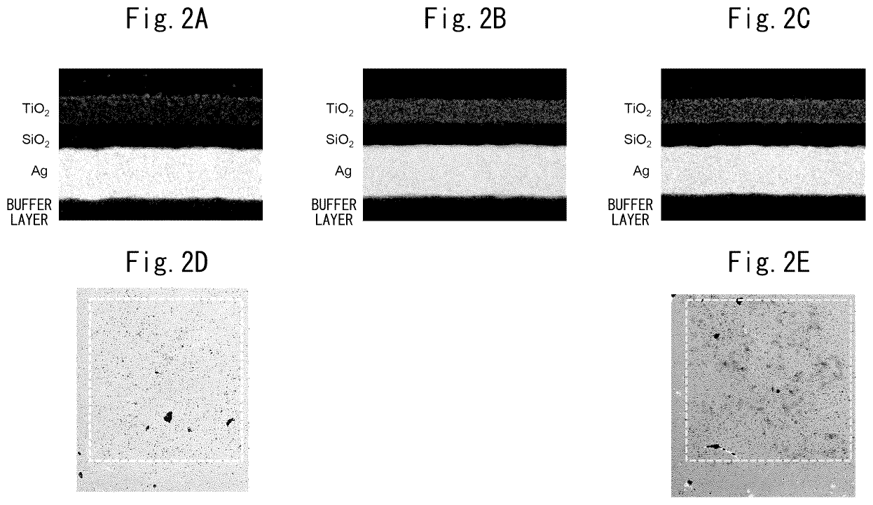

FIGS. 2A to 2E are diagrams showing the movement state of silver and FIG. 2A is a cross-sectional image of the multilayer reflection film when reflectance is comparatively high, FIG. 2B is a cross-sectional image of the multilayer reflection film when reflectance is reduced, and FIG. 2C is a cross-sectional image of the multilayer reflection film when reflectance is further reduced. FIG. 2D is a top surface image of the multilayer reflection film shown in FIGS. 2D and 2E is a top surface image of the multilayer reflection film shown in FIG. 2C.

FIGS. 2A to 2C are obtained by manufacturing a plurality of the LED light emitting devices as shown in FIGS. 1A to 1C and capturing the cross section of part of the multilayer reflection film, which is cut from the multilayer reflection film, as time elapses while keeping the LED die on. FIGS. 2D and 2E are obtained by capturing the top surface of the multilayer reflection film with the LED die removed before capturing the cross section in FIGS. 2A and 2C. Although the actual LED light emitting device has a sealing resin including fluorescent substance particles, the LED light emitting device for image capturing in FIG. 2A to 2E does not have a scaling resin.

FIGS. 2A and 2D show the state where the luminous flux residual ratio is 96.4%, which is an indicator indicating a change in luminous flux when the initial luminous flux is 100%, FIG. 2B shows the state where the luminous flux residual ratio is 93.0%, and FIGS. 2C and 2E show the state where the luminous flux residual ratio is 89.3%. Further, in FIGS. 2D and 2E, the broken line indicates the LED mount area in which the LED die is mounted.

In FIGS. 2A and 2D (state where the luminous flux residual ratio is comparatively high), the measuring density of silver of the titanium dioxide layer are 1.0 at %, and therefore almost no silver moves from the reflection layer to the titanium dioxide layer. The black point in FIG. 2D indicates the void in the reflection layer, which is caused by the movement of silver, and the black point occurs in an area of 3.2% with respect to the area of the LED mount area indicated by the broken line.

In FIG. 2B (state where the luminous flux residual ratio is reduced), the measuring density of silver in the titanium dioxide layer is 2.9 at % and therefore silver may move from the reflection layer to the titanium dioxide layer. The function of the reflection layer is reduced, since silver moves from the reflection layer, and therefore the luminous flux residual ratio is reduced.

In FIGS. 2C and 2E (state where the luminous flux residual ratio is further reduced), the measuring density of silver in the titanium dioxide layer is 3.8 at % and therefore the amount of silver moving from the reflection layer to the titanium dioxide layer has increased. The function of the reflection layer is largely reduced since silver moves more, and therefore the luminous flux residual ratio is further reduced. The black point (void in the reflection layer) in FIG. 2E occurs in the area of 11.3% with respect to the area of the LED mount area indicated by the broken line.

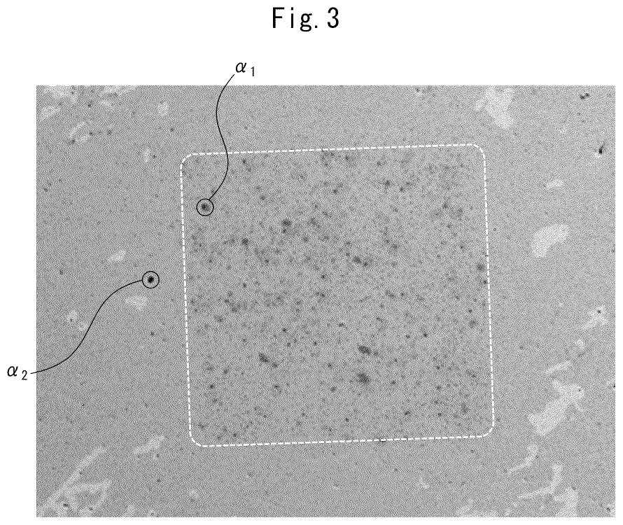

FIG. 3 is a top surface image of the multilayer reflection film. FIG. 3 is obtained by removing the LED die from the multilayer reflection film and capturing the top surface of the multilayer reflection film in the wide range including the LED die mount area in the state where the luminous flux residual ratio is reduced to the same level as that in FIG. 2C by utilizing one of the LED light emitting devices manufactured for image capturing of FIGS. 2A to 2E. In FIG. 3, the broken line indicates the LED mount area in which the LED die is mounted.

Although the black point (void in the reflection layer) in FIG. 3 occurs at many positions in the LED mount area, which is inside the broken line like a point α1, the black point occurs to a certain extent at some positions, which is outside the LED mount area like a point α2. The black point (void in the reflection layer) occurs at many positions in the LED mount area, since the area is the LED mount area where most of the blue light emitted from the LED die is irradiated. On the other hand, the outside of the LED mount area is also irradiated with the blue light emitted from the LED die, and therefore the black point (void in the reflection layer) occurs at some positions also outside the LED mount area.

As described above, the silver contained in the reflection layer included in the multilayer reflection film moves to the titanium dioxide layer included in the high reflection coating in which the reflection layer is laminated in response to the irradiation with the blue light emitted from the LED die. Thus, if a light shielding layer is arranged, which shields at least part of the blue light, between the reflection layer containing silver and the semiconductor laminate of the LED die, the movement of silver in accordance with the irradiation with the blue light in the LED mount area may be suppressed.

Part of the light emitted from the LED light emitting element is emitted from the light emitting layer of the LED die and emitted to the outside of the LED light emitting element after being reflected from the substrate surface within the light emitting area. Thus, it is important to protect the multilayer reflection film in the LED mount area, and further it is important to protect the multilayer reflection film outside the LED mount area in the light emitting area, in order to improve the reliability of the LED light emitting element.

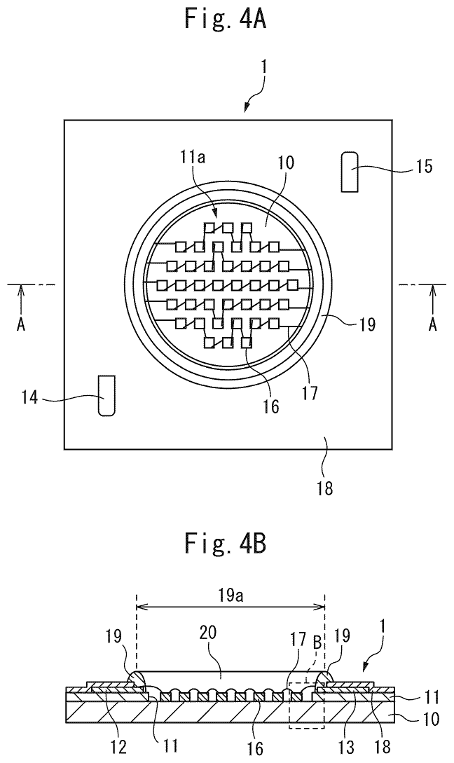

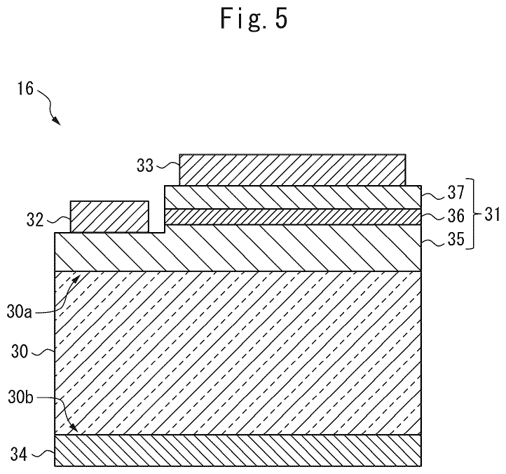

In FIG. 4 of U.S. Pat. No. 9,865,783, an example is described in which the LED having a low-refractive index layer on the undersurface is arranged on the substrate formed by laminating a high-refractive index layer 400 nm thick on a low-refractive index layer 800 nm thick. However, it is very difficult in terms of manufacture to arrange the thick layer uniformly on the whole substrate and may lead to a high cost. Further, the substrate is described in FIG. 5 of U.S. Pat. No. 9,865,783 which is formed by laminating a plurality of sets of a high-refractive index layer 20 to 200 nm thick and a low-refractive index layer 20 to 200 nm thick on the whole surface. However, it is very difficult in terms of manufacture to arrange a plurality of sets of the high-refractive index layer and the low-refractive index layer uniformly on the whole substrate and may lead to a high cost.

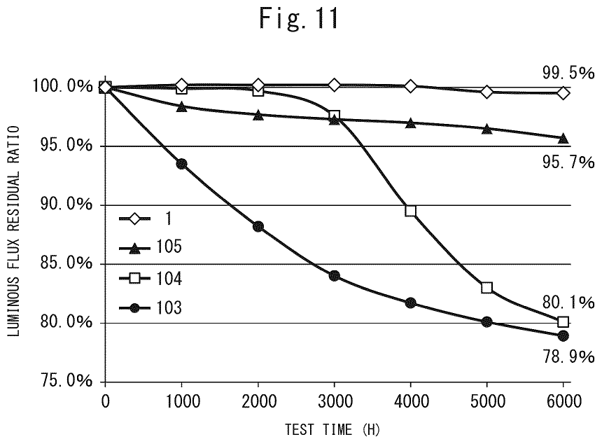

Thus, in the LED light emitting device according to the present disclosure, a multilayer reflection film including one TiO₂ layer and one SiO₂ layer, which are comparatively thin (the thickness of each layer is 30 to 100 nm), is formed on the whole surface of the substrate, and a DBR layer is arranged on the bottom surface of the LED die, in which a plurality of sets of dielectrics including a high-refractive index layer and a low-refractive index layer is laminated, so that the LED light emitting device may be manufactured both in a simple method and at a low cost with increasing the reflection of light from the multilayer reflection film. In the LED light emitting device according to the present disclosure, the multilayer reflection film in the LED mount area is protected by the DBR layer, and the surface of the multilayer reflection film outside the LED mount area in the light emitting area is protected by the fluorescent substance layer. In the LED light emitting device according to the present disclosure, the luminous flux residual ratio may be maintained at a high level for a long time with increasing the reflection of light from the multilayer reflection film (see FIG. 11).

In the LED light emitting device according to the present disclosure, the fluorescent substance particles are contained in the sealing resin and arranged inside a reflection frame, and the fluorescent substance particles are precipitated on the surface of the multilayer reflection film and form a fluorescent substance layer, by leaving for a predetermined time. When the fluorescent substance layer is formed, part of the blue light emitted from the light emitting layer of the LED die is converted into light of another color in the fluorescent substance layer, and therefore the amount of blue light with which the multilayer reflection film is irradiated decreases. Thus, compared to the case where the surface of the multilayer reflection film is irradiated directly with blue light, when the fluorescent substance layer is formed on the surface of the multilayer reflection film, the occurrence of the black point (void in the reflection layer) in the multilayer reflection film may be suppressed. Generally, the DBR layer has strong directivity for the incidence angle. In other words, the incidence angle of the blue light emitted from the light emitting layer of the LED die toward the outside of the LED mount area is large, and therefore, even if the DBR layer is arranged outside the LED mount area, the blue light is not reflected efficiently, and therefore the occurrence of the black point (void in the reflection layer) so much in the multilayer reflection film outside the LED mount area may be suppressed.

FIG. 4A is a plan diagram of the LED light emitting device 1 according to the embodiment, and FIG. 4B is a cross-sectional diagram along an A-A line shown in FIG. 4A.

The LED light emitting device 1 has a mount substrate 10, a circuit substrate 11, a pair of wiring patterns 12 and 13, a pair of electrodes 14 and 15, a plurality of LED dies 16, a bonding wire 17, a solder resist 18, a reflection frame 19, a sealing resin 20 and etc. The LED light emitting device 1 is a chip-on-board (COB) LED light emitting device.

The mount substrate 10 is s substrate having the shape of a rectangular plane and having a planar area on the surface of which the LED die 16 is mounted.

The circuit substrate 11 has the same shape of a plane as that of the mount substrate 10 and is adhered to the surface of the mount substrate 10, and an opening 11a is formed in the center of the circuit substrate 11. The pair of the wiring patterns 12 and 13 is formed on the top surface of the circuit substrate 11 so as to surround the opening 11a, and the pair of the electrodes 14 and 15 is formed in the vicinity of two angles facing diagonally, respectively.

The electrode 14 is an anode electrode, and the electrode 15 is a cathode electrode. The pair of the electrodes 14 and 15 is connected to an external power supply, not shown schematically, and the LED light emitting device 1 emits light when a predetermined voltage is applied between the pair of the electrodes 14 and 15.

The LED die 16 is mounted on the mount substrate 10 exposed from the opening 11a by an insulating adhesive. FIGS. 4A and 4B show an example in which the LED light emitting device 1 has the 40 LED dies 16.

The bonding wires 17 are formed of electrically conductive members, such as gold, and connect a cathode 32 and an anode 33 to each other of the adjacent LED die 16. Further, the bonding wires 17 connect the LED dies 16 adjacent to the outer edge of the opening 11a and the wiring patterns 12 and 13 to each other. In the LED light emitting device 1, five columns in each of which the eight LED dies 16 are connected in series via the bonding wires 17 are connected in parallel to the wiring patterns 12 and 13. However, the number of LED dies 16 connected in series and the number of columns connected in parallel may be determined appropriately for the LED die according to the embodiment.

The solder resist 18 is a heat-resistant insulating resin, such as an epoxy resin, and arranged on the circuit substrate 11 so as to cover the outside of the opening 11a across the whole surface of the pair of the wiring patterns 12 and 13 except for the pair of the electrodes 14 and 15.

The reflection frame 19 is a resin containing fillers, such as silica, in a synthetic resin, such as a silicone resin, and arranged along the outer edge of the opening 11a so as to cover the wiring patterns 12 and 13. The reflection frame 19 reflects the blue light emitted from the LED die 16 and emits the blue light toward above the LED light emitting device 1, in other words, toward the direction opposite to the mount substrate 10 of the LED die 16. The area inside the reflection frame 19 is taken as a light emitting area 19a.

The sealing resin 20 is a colorless and transparent synthetic resin, such as an epoxy resin and a silicone resin, and arranged inside the reflection frame 19 and covers the LED die 16 and the boding wires 17 integrally. Green fluorescent substance particles also referred to as first fluorescent substances such as Y₃Al₅O₁₂:Ce (Yttrium Aluminum Garnet, YAG), and red fluorescent substance particles also referred to as second fluorescent substances such as CaAlSiN₃:Eu (CASN) are mixed in the sealing resin 20. The green fluorescent substance particles and the red fluorescent substance particles are precipitated and arranged so as to cover the surface of the mount substrate 10 and at least part of the surface and the lateral surface of the LED die 16. The LED light emitting device 1 emits white light by mixing the blue light from the LED die and green light and red light obtained by part of the blue light exciting the green fluorescent substance and the red fluorescent substance. The fluorescent substances that are mixed into the sealing resin 20 is not limited to the above-described two types of fluorescent substance and an arbitrary combination of fluorescent substances whose at least one of composition and particle diameter is different may be selected.

FIG. 5 is a cross-sectional diagram of the LED die 16.

The LED die 16 has a transparent substrate 30, a semiconductor laminate 31, the cathode 32 and the anode 33, and a DBR (Distributed Bragg Reflector) layer 34 is arranged on the undersurface of the LED die 16. The transparent substrate 30 is formed of a transparent material through which light passes, such as sapphire and spinel, and has a first surface 30a on which the semiconductor laminate 31 is laminated and a second surface 30b on which the DBR layer 34 is laminated. The thickness of the transparent substrate 30 is, for example, 200 μm, and preferably 100 μm or more. The amount of blue light entering the fluorescent substance contained in the sealing resin 20 increases and the amount of blue light entering the mount substrate 10 decreases, by increasing the film thickness of the transparent substrate 30.

The semiconductor laminate 31 has an n-type semiconductor layer 35, a light emitting layer 36 and a p-type semiconductor layer 37. The n-type semiconductor layer 35 has gallium nitride (GaN) doped with, for example, silicon (Si). Further, the light emitting layer 36 has a well layer and a barrier layer of gallium nitride doped with aluminum (Al) and indium (In). Furthermore, the p-type semiconductor layer 37 has gallium nitride doped with magnesium (Mg).

The cathode 32 and the anode 33 are each a metal electrode layer including a metal of one of, for example, Al, Cu, Au, Pt, Pd, Rh, Ni, W, Mo, Cr and Ti, or an alloy of these metals, or a combination of these metals and alloys. The cathode 32 is laminated on the n-type semiconductor layer 35, and the anode 33 is laminated on the p-type semiconductor layer 37. The light emitting layer 36 emits blue light when a predetermined forward voltage is applied between the cathode 32 and the anode 33. The peak wavelength of the blue light emitted by the LED die 16 is 430 nm to 470 nm.

The DBR layer 34 has a multilayer structure in which a plurality of sets of dielectrics including a high-refractive index layer and a low-refractive index layer is laminated and efficiently reflects the blue light emitted from the light emitting layer 36. The high-refractive index layer is selected from a group including TiO₂, ZrO₂, ZnSe, Si₃N₄, Nb₂O₅, TaO₅, and HfO₂, and the low-refractive index layer is selected from a group including SiO₂, MgF₂, Al₂O₃, and CaF. It is preferable for the film thickness of each layer configuring the DBR layer 34 to be 20 to 150 nm. In the DBR layer 34, it is preferable for about five to 30 sets of dielectrics including a high-refractive index layer and a low-refractive index layer to be laminated. Further, the LED die 16 may have a metal film selected from a group including Al, Ag, Pt, and Pd as well as the DBR layer 34.

When the LED die 16 is mounted on the mount substrate 10 and connected by the boding wires 17, the cathode 32 and the anode 33 are located at the uppermost portion of the LED die 16 and the light emitting layer 36 is also located at substantially the uppermost portion of the LED die 16. Specifically, the p-type semiconductor layer 37, the light emitting layer 36, and the n-type semiconductor layer 35 are very thin, and therefore the height of the light emitting layer 36 is substantially the same as the thickness of the transparent substrate 30.

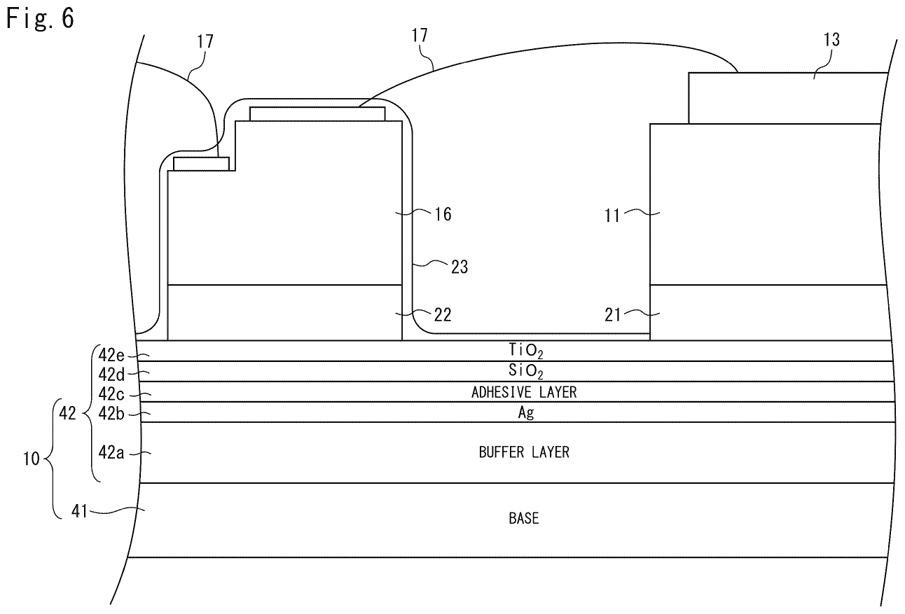

FIG. 6 is an enlarged diagram of a B portion in FIG. 4B.

In FIG. 6, part of the mount substrate 10 and the circuit substrate 11 and one of the 40 LED dies 16 mounted on the mount substrate 10 are shown. In FIG. 6, the positional relationship of each component is shown schematically and the relationship between size of each component is not necessarily exact. Further, in FIG. 6, the description of the reflection frame 19 and the scaling resin 20 is omitted.

The LED light emitting device 1 has an adhesive material 21 which adheres the circuit substrate 11 to the mount substrate 10, a die bond material 22 which mounts the LED die 16 on the mount substrate 10, and a transparent material 23 arranged so as to cover the surface of the mount substrate 10 and at least part of the surface and the lateral surface of the LED die. The adhesive material 21 is an adhesive member, for example, such as a silicone resin base or an epoxy resin base. Further, the die bond material 22 is an adhesive member including a synthetic resin, for example, such as a silicone resin base or a polyimide silicone resin base. The transparent material 23 is a light transmitting member formed of an acryl component, a fluorine component, a silicone component, a metal oxide and etc., and the rigidity of the transparent material 23 may be higher than that of the sealing resin 20. Further, the transparent material 23 may be the same synthetic resin material as the sealing resin 20.

As shown in FIG. 6, the mount substrate 10 has a base 41 and a multilayer reflection film 42 formed on one of the surfaces of the base 41. The base 41 may be a metal including aluminum, copper and etc., or ceramics including alumina, aluminum nitride and etc.

The multilayer reflection film 42 has a reflection layer including at least a buffer layer 42a and a Ag layer 42b from the side of the base 41, an adhesive layer 42c, a SiO₂ layer 42d, and a TiO₂ layer 42e. The SiO₂ layer 42d and the TiO₂ layer 42e may be referred to as a high resolution coating. The adhesive layer 42c is arranged for improving adhesion between the Ag layer 42b and the SiO₂ layer 42d.

The buffer layer 42a has functions of insulation, prevention of diffusion of silver, adhesion and etc., between the base 41 and the Ag layer 42b, and is a multilayer film including at least an anodized aluminum layer.

The adhesive layer 42c functions as an adhesive layer for adhering the Ag layer 42b and the SiO₂ layer 42d each other. The thickness of the adhesive layer 42c is, for example, 5 nm and preferably, not less than 0.5 nm and not more than 10 nm.

The SiO₂ layer 42d and the TiO₂ layer 42e are laminated above the Ag layer 42b, and function as a protection layer for preventing silver included in the Ag layer 42b from being sulfurized. Further, the refractive index of the SiO₂ layer 42d is lower than that of the TiO₂ layer 42c, and the reflection of the light emitted from the LED die 16 to the side of the mount substrate 10 toward above the LED light emitting device 1 is increased by the difference in the refractive index between the SiO₂ layer 42d, which is a low-refractive index layer, and the TiO₂ layer 42c, which is a high-refractive index layer. Thus, the SiO₂ layer 42d and the TiO₂ layer 42e function as a high reflection coating for increasing the reflection of the light emitted from the LED die 16 to the side of the mount substrate 10 toward above the LED light emitting device 1. The thickness of the SiO₂ layer 42d is, for example, 65 nm and not less than 30 nm and not more than 100 nm. The thickness of the TiO₂ layer 42e is, for example, 50 nm and not less than 30 nm and not more than 100 nm. The multilayer reflection film 42 has a pair of the SiO₂ layer 42d and the TiO₂ layer 42c.

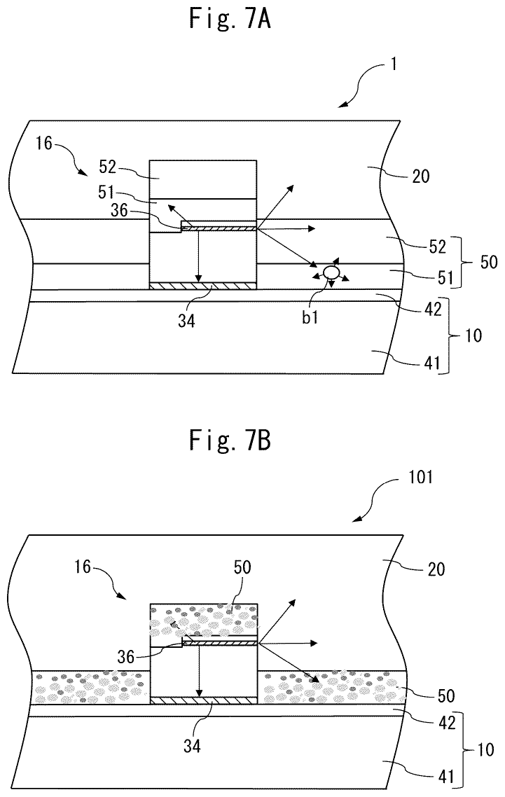

FIG. 7A and FIG. 7B are each a schematic diagram for explaining a relationship between an LED die and a fluorescent substance layer. FIG. 7A shows the state of the fluorescent substance layer in the LED light emitting device 1 and FIG. 7B shows the state of the fluorescent substance layer in the LED light emitting device 101, which is a modification example of the LED light emitting device 1. In FIG. 7A and FIG. 7B, the description of the cathode 32 and the anode 33 of the LED die 16 shown in FIG. 5 and the die bond material 22 and the transparent material 23 shown in FIG. 6 is omitted. The LED light emitting device 101 is identical to the LED light emitting device 1 except for the precipitation state of the fluorescent substance particles.

As described previously, in the LED light emitting device 1, the green fluorescent substance particles and the red fluorescent substance particles are mixed into the sealing resin 20. Further, fillers of 5 wt % with respect to the sealing resin 20 are mixed into the sealing resin 20. Thus, most of the green fluorescent substance particles whose average particle diameter is large precipitate downward, whereas part of the red fluorescent substance particles whose average particle diameter is small compared to that of the green fluorescent substance particles do not precipitate completely and are in the state of floating somewhat. Part of the red fluorescent substance particles are arranged between the green fluorescent substance particles. Since part of the red fluorescent substance particles are arranged between the green fluorescent substance particles, the void between the green fluorescent substance particles whose average particle diameter is large is filled with the red fluorescent substance particle, and therefore that the blue light emitted from the LED die 16 may not reach the multilayer reflection film 42.

Thus, in the LED light emitting device 1, as shown in FIG. 7A, the fluorescent substance particles precipitate within the sealing resin 20 and form a fluorescent substance layer 50. In detail, a cohesive layer 51 is formed in the lower portion of the fluorescent substance layer 50, in which most of the green fluorescent substance particles and part of the fluorescent substance particles cohere, and covers the surface of the multilayer reflection film 42 of the mount substrate 10 including the surface of the LED die 16 and part of the lateral surface of the LED die 16. Further, a floating layer 52 is formed on the cohesive layer 51, in which part of the green fluorescent substance particles and most of the red fluorescent substance particles exist while floating somewhat.

In the LED light emitting device 101 shown in FIG. 7B, which is a modification example, almost no fillers are mixed into the sealing resin 20. Thus, most of the green fluorescent substance particles and the red fluorescent substance particles precipitate completely, and the fluorescent substance layer 50 in which those particles cohere is formed on the surface of the mount substrate 10 so as to cover the surface of the LED die 16 and part of the lateral surface of the LED die 16. Thus, the fluorescent substance layer 50 is formed as a cohesive layer and the floating layer 52 hardly exists. The degree of cohesion of the fluorescent substance layer 50 in the LED light emitting device 101 is higher than the degree of cohesion of the fluorescent substance particles in the cohesive layer 51 of the LED light emitting device 1.

In FIG. 7B, large-diameter fluorescent substance particles (green fluorescent substance particles), small-diameter fluorescent substance particles (red fluorescent substance particles), and rectangular fillers are described in order to indicate the degree of cohesion of the fluorescent substance layer 50. In the actual LED light emitting devices 1 and 101, some amount of fluorescent substance particles that do not precipitate completely may float in the portion of the scaling resin 20 not shown as the fluorescent substance layer 50.

As shown in FIG. 7A, the blue light emitted directly downward from the light emitting layer 36 is reflected efficiently from the DBR layer 34 and the amount of light with which the multilayer reflection film 42 is irradiated is reduced, and therefore the buffer layer 42a may not be exposed by the movement of the silver in the Ag layer 42b as shown in FIGS. 1A to 1C. On the other hand, part of the blue light emitted around the LED die 16 from the light emitting layer 36 is absorbed by the fluorescent substance particle (b1) configuring particularly the cohesive layer 51 of the fluorescent substance layer 50 formed by the fluorescent substance particles cohering and wavelength-converted into light of a color other than blue and emitted from the fluorescent substance particle (b1). Thus, the amount of the blue light with which the multilayer reflection film 42 is irradiated is reduced finally, and therefore the buffer layer 42a may not be exposed by the movement of the silver in the Ag layer 42b as shown in FIGS. 1A to 1C.

As above, in the LED light emitting device 1, since the DBR layer 34 is arranged on the undersurface of the LED die 16 and the fluorescent substance layer 50 is arranged on the surface of the multilayer reflection film 42 around the LED die 16, in the whole light emitting area 19a, the buffer layer 42a is may not be exposed by the movement of the silver in the Ag layer 42b as shown in FIGS. 1A to 1C.

On the other hand, in the LED light emitting device 101 shown in FIG. 7B, which is the modification example, the fluorescent substance layer 50 whose degree of cohesion is higher than that of the cohesive layer 51 in the LED light emitting device 1 is formed. Thus, similar to the LED light emitting device 1, the buffer layer 42a may not be exposed by the movement of the silver in the Ag layer 42b in the whole light emitting area 19a as shown in FIGS. 1A to 1C.

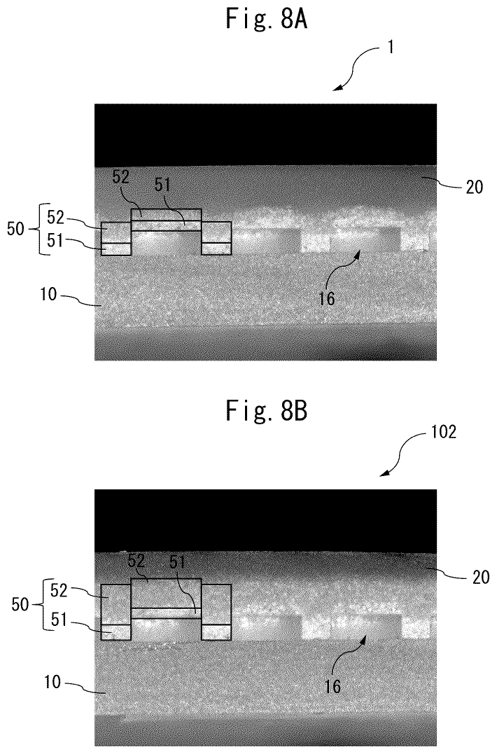

FIG. 8A shows a cross-sectional image of the LED light emitting device 1 and FIG. 8B shows a cross-sectional image of the LED light emitting device 102, which is the modification example of the LED light emitting device 1.

As shown in FIG. 8A, in the LED light emitting device 1, the LED dies 16 are arranged close to one another, and therefore the fluorescent substance layer 50 is formed between a plurality of the LED dies 16 and on the surface of each LED die 16. The cohesive layer 51, which is the lower portion of the fluorescent substance layer 50, is formed on the side of the surface of the mount substrate 10 and the floating layer 52 is formed on the cohesive layer 51.

FIG. 8B is a cross-sectional image of the LED light emitting device 102, which is the modification example of the LED light emitting device 1. The LED light emitting device 102 is identical to the LED light emitting device 1 except for the filler mixing ratio into the scaling resin 20. As described previously, in the LED light emitting device 1, fillers of 5 wt % are mixed into the sealing resin 20, whereas in the LED light emitting device 102 shown in FIG. 8B, fillers of 10 wt % are mixed.

In the LED light emitting device 102, the filler mixing ratio is different, and therefore the width of the floating layer 52 in which part of the green fluorescent substance particles and many red fluorescent substance particles are included increases. However, most of the green fluorescent substance particles and part of the red fluorescent substance particles precipitate and the cohesive layer 51 in which those fluorescent substance particles cohere is formed firmly on the side of the surface of the mount substrate 10.

If the uncured scaling resin 20 is arranged within the reflection frame 19 and is left for a predetermined time, the fluorescent substance particles whose specific gravity is larger than the transparent synthetic resin, which is the binder of the sealing resin 20, precipitate downward. Thus, when the sealing resin 20 is cured after the predetermined time, the state of the fluorescent substance layer 50 in FIGS. 8A and 8B is maintained. There is a correlation between the content (wt %) of fillers mixed into the sealing resin 20 and the formation of the fluorescent substance layer 50. It is preferable to mix fillers of 0 to 10 wt % into the sealing resin 20, in order to form the desired fluorescent substance layer 50.

It is preferable for the average particle diameter (particle diameter of each individual primary particle in the non-cohesion state) of the filler contained in the sealing resin 20 to be about 1 μm to 25 μm and further preferable to be about 5 μm to 10 μm. The shape of the filler is a crushed shape or a spherical shape and includes silicon dioxide (silica), alumina, titanium dioxide, zirconia, magnesia and etc. Further, in addition to the filler of the micron order, the filler whose particle diameter is the nano size may be included in the filler, in order to adjust the viscosity of the sealing resin 20 and the precipitation state of the fluorescent substance particle. It is preferable for the filler to have a heat-resisting property and be easily absorbed to the fluorescent substance particle.

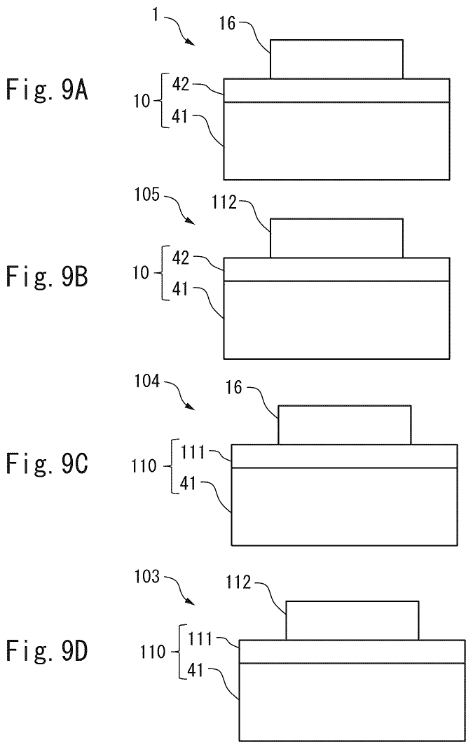

FIG. 9A is a schematic diagram showing the mount substrate and the LED die used in the LED light emitting device 1, FIG. 9B is a schematic diagram showing those used in the LED light emitting device 105 according to the third comparative example, FIG. 9C is a schematic diagram showing those used in the LED light emitting device 104 according to the second comparative example, and FIG. 9D is a schematic diagram showing those used in the LED light emitting device 103 according to the first comparative example, respectively.

Although the sealing resin 20, the fluorescent substance layer 50 and etc., are omitted in FIGS. 9A to 9D, the fluorescent substance layer 50 as shown in FIG. 7A is formed in each LED light emitting device.

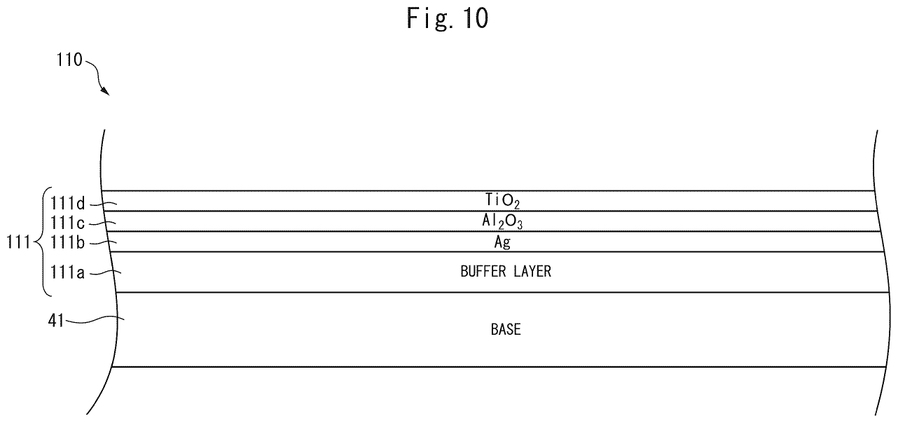

The LED light emitting device 103 according to the first comparative example shown in FIG. 9D differs from the LED light emitting device 1 shown in FIG. 9A only in the mount substrate and the LED die. The LED die 112 of the LED light emitting device 103 is the LED die 16 from which the DBR layer 34 is removed and the mount substrate of the LED light emitting device 103 is a mount substrate 110 shown in FIG. 10.

The LED light emitting device 104 according to the second comparative example shown in FIG. 9C differs from the LED light emitting device 1 shown in FIG. 9A only in the mount substrate to be used. The mount substrate of the LED light emitting device 104 is the mount substrate 110 shown in FIG. 10.

The LED light emitting device 105 according to the third comparative example shown in FIG. 9B differs from the LED light emitting device 1 shown in FIG. 9A only in the LED die. The LED die 112 of the LED light emitting device 105 is the LED die 16 from which the DBR layer 34 is removed.

FIG. 10 is a diagram showing the mount substrate 110 of the LED light emitting devices 103 and 104 according to the comparative examples. As shown in FIG. 10, the mount substrate 110 has a multilayer reflection film 111 formed on one of the surfaces of the base 41 and functioning as a light reflection system. The base 41 is the same as that of the LED light emitting device 1 and the multilayer reflection film 111 has at least a buffer layer 111a, an Ag layer 111b, an Al₂O₃ layer 111c, and a TiO₂ layer 111d from the side of the base 41.

In the multilayer reflection film 111, in place of the SiO₂ layer 42d of the multilayer reflection film 42 in the LED light emitting device 1, the Al₂O₃ layer 111c is utilized whose adhesion with the Ag layer is high and whose invasiveness of silver is somewhat high. Thus, the multilayer reflection film 111 does not have a layer corresponding to the adhesive layer 42c of the multilayer reflection film 42 in the LED light emitting device 1. However, in the multilayer reflection film 111, compared to the multilayer reflection film 42, when blue light is irradiated, silver move from the Ag layer 111b to the Al₂O₃ layer 111c, and therefore the buffer layer 111a may be easily exposed.

FIG. 11 is a diagram showing the luminous flux residual ratio of each of the LED light emitting device 1, the LED light emitting device 103 according to the first comparative example, the LED light emitting device 104 according to the second comparative example and the LED light emitting device 105 according to the third comparative example. The luminous flux residual ratio shown in FIG. 11 is obtained under the conditions that the temperature of the electrode 15, which is the cathode electrode, is 105° C. and the input power is 170 W.

In the LED light emitting device 1 according to the embodiment, the luminous flux residual ratio after a lapse of 6,000 hours is 99.5%. On the other hand, in the LED light emitting device 103 according to the first comparative example, the luminous flux residual ratio after a lapse of 6,000 hours is 78.9% and in the LED light emitting device 104 according to the second comparative example, the luminous flux residual ratio after a lapse of hours is 80.1%. Further, in the LED light emitting device 105 according to the third comparative example, the luminous flux residual ratio after a lapse of 6,000 hours is 95.7%.

In the luminous flux residual ratio after a lapse of 6,000 hours, the difference between the LED light emitting device 1 and the LED light emitting device 104 whose mount substrate is different from that of the LED light emitting device 1 is 19.4%.

In the luminous flux residual ratio after a lapse of 6,000 hours, the difference between the LED light emitting device 1 and the LED light emitting device 105 whose mount substrate is different from that of the LED light emitting device 1 is 3.8%. In the luminous flux residual ratio after a lapse of 6,000 hours, the difference between the LED light emitting device 1 and the LED light emitting device 105 is smaller than 19.4%, which is the difference between the LED light emitting device 1 and the LED light emitting device 104. However, the difference between the LED light emitting device 1 and the LED light emitting device 105 is three times or more 1.2%, which is the difference between the LED light emitting device 103 and the LED light emitting device 104 whose mount substrate to be used is similarly different from that of the LED light emitting device 103.

Measured luminous flux residual ratios of the LED light emitting device 101 shown in FIG. 7 and the LED light emitting device 102 shown in FIG. 8 are the same as those of the LED light emitting device 1 shown in FIG. 11. Although not shown schematically, the luminous flux residual ratio after a lapse of 6,000 hours in the LED light emitting device according to the comparative example in which the fluorescent substance layer 50 as shown in FIG. 7A in the LED light emitting device 1 is not formed is lower than the luminous flux residual ratio after a lapse of 6,000 hours in the LED light emitting device 105 according to the third comparative example.

As shown in FIG. 11 and etc., only in the LED light emitting devices 1, 101 and 102 having the DBR layer 34 arranged on the undersurface of the LED die 16 and the fluorescent substance layer 50 arranged on the surface of the multilayer reflection film 42 around the LED die 16, the luminous flux residual ratio properties may be improved, which is one of the reliability requirement items. Since the LED light emitting devices 1, 101 and 102 have the DBR layer 34 and the fluorescent substance layer 50, the buffer layer 42a may not be exposed by the movement of silver in the Ag layer 42b as shown in FIGS. 1A to 1C in the whole light emitting area 19a.

### OTHER MODIFICATION EXAMPLES

As shown in FIG. 6, in the LED light emitting device 1, the transparent material 23 is arranged so as to cover the surface of the mount substrate 10 and at least part of the surface and the lateral surface of the LED die 16. When the transparent material 23 is irradiated with blue light, the transparent material 23 contacting with the multilayer reflection film 42 is reduced, and therefore a stress occurs in the multilayer reflection film 42 and the Ag layer 42b and SiO₂ layer 42d may peel off from each other. However, in the LED light emitting device 1, the amount of blue light with which the transparent material 23 is irradiated is reduced, and therefore the invasion of silver from the Ag layer 42b into the TiO₂ layer 42e is suppressed. On the other hand, when the transparent material 23 exists, the sealing resin 20 is highly adhered to the surface of the mount substrate 10. Since the sealing resin 20 is highly adhered to the surface of the mount substrate 10, the fluorescent substance layer 50 is highly adhered to the surface of the mount substrate 10, and therefore of the buffer layer 42a may not be exposed.

As shown in FIG. 6, in the LED light emitting device 1, the LED die 16 is mounted on the mount substrate 10 with the die bond material 22. The die bond material 22 may contain oxides, such as titanium dioxide, alumina, and silica, as particles of a reflective material. In this case, the blue light may be reflected by both the DBR layer 34 and the die bond material 22. Further, the die bond material 22 may contain fluorescent substance particles. When the die bond material 22 contains fluorescent substance particles, the die bond material 22 is formed as a fluorescent substance layer, and therefore the amount of blue light with which the multilayer reflection film 42 is irradiated both in the DBR layer 34 and in the die bond material 22 may be further reduced.

As shown in FIG. 7A, the blue light is emitted from the light emitting layer 36 of the LED die 16. It is preferable for at least part of the fluorescent substance layer 50, particularly for the cohesive layer 51 to be formed under the light emitting layer 36 of the LED die 16 in order to protect the surface of the multilayer reflection film 42 efficiently and suppress the exposure of the buffer layer 42a.

1. An LED light emitting device comprising:
a mount substrate having a base, a reflection layer containing silver and laminated on the base, and a multilayer reflection film laminated on the reflection layer;
an LED die emitting blue light and mounted in a light emitting area on the mount substrate;
a sealing resin including fluorescent substance particles and sealing the LED die and the surface of the mount substrate within the light emitting area;
a DBR layer arranged on the undersurface of the LED die and shielding at least part of blue light emitted from the LED die; and
a transparent material arranged between the multilayer reflection film and the sealing resin so as to cover at least part of the surface and the lateral surface of the LED die, wherein
the DBR layer is a layer in which a plurality of sets of dielectrics including a high-refractive index layer and a low-reflective index layer is laminated, and
the fluorescent substance particles precipitate within the sealing resin and form a fluorescent substance layer covering part of the lateral surface of the LED die and part of the surface of the multilayer reflection film within the light emitting area.

2. The LED light emitting device according to claim 1, wherein
the fluorescent substance layer includes a cohesive layer in which fluorescent substance particles cohere.

3. The LED light emitting device according to claim 1, wherein
the fluorescent substance layer includes a cohesive layer in which fluorescent substance particles cohere and a floating layer in which fluorescent substance particles float.

4. The LED light emitting device according to claim 1, further comprising:
a circuit substrate fixed on the mount substrate; and
a wiring pattern arranged on the circuit substrate, wherein
the LED die has a transparent substrate, a semiconductor laminate having a light emitting layer laminated on the transparent substrate, and a pair of electrodes connected to the semiconductor laminate and emits blue light from the light emitting layer in response to a predetermined voltage being applied between the pair of electrodes via the wiring pattern and
at least part of the fluorescent substance layer is formed between the light emitting layer and the multilayer reflection film.

5. The LED light emitting device according to claim 4, wherein
the fluorescent substance particles include first fluorescent substance particles and second fluorescent substance particles whose average particle diameter is smaller than that of the first fluorescent substance particles and
part of the second fluorescence substance particles are arranged between the first fluorescence substance particles.

6. The LED light emitting device according to claim 1, wherein
the high-refractive index layer is selected from a group including TiO₂, ZrO₂, ZnSe, Si₃N₄, Nb₂O₅, TaO₅, and HfO₂ and
the low-refractive index layer is selected from a group including SiO₂, MgF₂, Al₂O₃, and CaF.

7. The LED light emitting device according to claim 1, further comprising:
a metal film arranged between the undersurface of the LED die and the multilayer reflection film.

8. The LED light emitting device according to claim 1, further comprising:
a die bond material for mounting the LED die on the mount substrate, wherein the die bond material contains reflective material particles.

9. The LED light emitting device according to claim 1,
wherein
the sealing resin contains fillers of 5 to 10 wt % with respect to the sealing resin.

10. The LED light emitting device according to claim 1,
wherein
the multilayer reflection film includes one TiO₂ layer and one SiO₂ layer.

11. The LED light emitting device according to claim 10,
wherein
the film thickness of each of the TiO₂ layer and the SiO₂ layer configuring the multilayer reflection film is 30 to 100 nm.

12. The LED light emitting device according to claim 4, wherein
the number of the LED die is two or more, and
at least part of the fluorescent substance layer is formed between the LED dies.
